(19) United States
(12) Patent Application Publication
(10) Pub. No.: US 2016/0315224 A1
(43) Pub. Date: Oct. 27, 2016

(54) NITRIDE SEMICONDUCTOR ELEMENT

(71) Applicant: SHARP KABUSHIKI KAISHA, Osaka-shi, Osaka (JP)

(72) Inventor: Satoshi KOMADA, Osaka-shi (JP)

(21) Appl. No.: 15/104,291

(22) PCT Filed: Jan. 21, 2015
(86) PCT No.: PCT/JP2015/051480

§ 371 Date: Jun. 14, 2016

(30) Foreign Application Priority Data
Jan. 28, 2014 (JP) 2014-012934

(51) Int. Cl. H01L 33/24; H01L 33/32; H01L 33/42; H01L 33/06

(52) U.S. Cl. CPC H01L 33/24; H01L 33/06; H01L 33/32; H01L 33/42

(57) ABSTRACT

A nitride semiconductor element includes: a substrate having a concave-convex surface; a nitride semiconductor under-layer on the substrate; and a nitride semiconductor function layer on the nitride semiconductor under-layer. The nitride semiconductor under-layer includes a concave-convex face as the surface that is composed of inclined faces which are inclined at an angle of 50° to 65° to a C-plane. The nitride semiconductor function layer is provided on the concave-convex face of the nitride semiconductor under-layer.

### TECHNICAL FIELD

The present invention relates to a nitride semiconductor element.

### BACKGROUND ART

For example, in a nitride semiconductor-based light-emitting diode, a lattice constant in an a-axis direction changes by the composition of a group 3 element, and thus a piezoelectric field is generated in a heterojunction. Thereby, the wave function of a valence band and the wave function of a conduction band are spatially separated, and a matrix element that is an element for determining a light-emitting recombination lifetime becomes small. Thus, the light-emitting efficiency theoretically decreases. Therefore, a semi-polar technique and a non-polar technique by which a small amount of polarization occurs or by which polarization does not occur have been proposed.

For example, in NPL 1, an attempt by which a GaN substrate is cut using a semi-polar face and growth is performed on the face has been made. As another method, there is a method of obtaining a non-polar face by the growth onto an R-plane sapphire substrate (NPL 2) or by the growth from concave-convex side walls.

In addition, NPL 4 discloses a method by which a trapezoidal-shaped n-GaN array having inclined faces is formed in a stripe pattern on a C-plane (0001) of a n-GaN layer in which a stripe-shaped SiO₂ mask is partially provided, and then a InGaN/GaN multiple quantum well (MQW) light-emitting layer is formed so as to cover the n-GaN array. In NPL 4, a light-emitting wavelength from the MQW light-emitting layer grown on the C-plane is different from a light-emitting wavelength from the MQW light-emitting layer grown on the inclined faces of the n-GaN array, and thus it is reported that an LED which emits two-color light can be obtained.

### CITATION LIST

### Non Patent Literature

NPL 1: Y. Kawaguchi et al., “Dependence of Electron Overflow on Emission Wavelength and Crystallographic Orientation in Single-Quantum-Well III-Nitride Light-Emitting Diodes”, Applied Physics Express 6 (2013) 052103
NPL 2: R. Miyagawa et al., “Reactor-pressure dependence of growth of a-plane GaN on r-plane sapphire by MOVPE”, Journal of Crystal Growth 310 (2008) 4979-4982
NPL 3: Daniel F. Feezell., “Semipolar (20-2-1) InGaN/GaN Light-Emitting Diodes for High-Efficiency Solid-State Lighting”, JOURNAL OF DISPLAY TECHNOLOGY
NPL 4: Chu-Young Cho et al., “InGaN/GaN multiple quantum wells grown on microfacets for white-light generation”, APPLIED PHYSICS LETTERS 93, 241109 (2008) 241109-1-241109-3

### SUMMARY OF INVENTION

### Technical Problem

For example, as problems in a case where the GaN substrate disclosed in NPL 1 is used, there are problems that it is difficult to realize a large diameter, the cost is high, and the like.

In addition, in a case where the GaN substrate is used in a ultraviolet region, light-absorption occurs, and thus it causes a loss in the efficiency. An AlN substrate in which light-absorption is small compared to the GaN substrate still has a big technical hurdle, and thus the AlN substrate is not yet widely used. Also, in a GaN crystal disclosed in NPL 2 that is epitaxially grown on the R-plane sapphire substrate, full width at half maximum of XRD is large, as large as 700 arcsec in a c-axis direction and 1200 arcsec in an m-axis direction (main plane), and dislocation density is high. Thus, high-quality crystal growth has not been established. In addition, in principle, a face defect (stacking fault) is propagated upward at a high density, and thus the face defect has a great effect on crystallinity. Even in the growth from concave-convex side walls, it is necessary to laminate a protective film, and thus the process becomes complicated. In addition, it is also difficult to control the growth from the concave-convex side walls.

Furthermore, the LED described in NPL 4 emits two-color light, and thus it is difficult to obtain a high-efficiency LED using a single-color light emission. In addition, the LED is formed by arranging the stripe-shaped SiO₂ mask, and thus it is difficult to sufficiently increase the light-emitting volume. Further, there is also a problem that a step of placing the SiO₂ mask is required.

### Solution to Problem

An embodiment disclosed herein provides a nitride semiconductor element including: a substrate having a concave-convex surface; a nitride semiconductor under-layer on the substrate; and a nitride semiconductor function layer on the nitride semiconductor under-layer, in which the nitride semiconductor under-layer includes a concave-convex face as the surface that is composed of inclined faces which are inclined at an angle of 50° to 65° to a C-plane, and in which the nitride semiconductor function layer is provided on the concave-convex face of the nitride semiconductor under-layer.

For example, in the case of using this technique, even when an R-plane GaN substrate or an N-plane GaN substrate is not used, it is possible to suppress the piezoelectric field by using a sapphire substrate, a spinel substrate, a SiC (silicon carbide) substrate, a Si (silicon) substrate, or the like which is subjected to concave-convex machining, thereby improving the light-emitting efficiency of the light-emitting element. Further, it is possible to increase the light extraction efficiency by exposing the concave-convex face. Further, it is also possible to reduce an operating voltage by increasing the contact area. The sapphire substrate can be used because the absorption coefficient thereof is small even in the ultraviolet region. In addition, the sapphire substrate is grown while obtaining a driving force (kinetics) of the stable C-plane, and thus it is possible to grow the sapphire substrate with high quality crystallinity that is not different from that of the C-plane.

In the present invention, the concave-convex face is formed such that at least one of an R-plane and an N-plane is exposed. The exposure means that at least one of the R-plane and the N-plane of the concave-convex face is exposed on the layer (nitride semiconductor under-layer) under the nitride semiconductor function layer which functions as a light-emitting layer, a light-receiving layer, or the like, and the nitride semiconductor function layer such as the light-emitting layer, the light-receiving layer, or the like is laminated on the surface of at least one of the R-plane and the N-plane of the concave-convex face. Therefore, the nitride semiconductor function layer such as the light-emitting layer or the light-receiving layer is formed along the inclined faces included in the concave-convex face (oblique facet face). The nitride semiconductor function layer such as the light-emitting layer, the light-receiving layer, or the like may be buried in a layer to be laminated thereon. However, considering from the viewpoint of the light extraction efficiency, a structure in which the nitride semiconductor function layer such as the light-emitting layer, the light-receiving layer, or the like is not buried is preferable. In addition, the R-plane and the N-plane exposed by the facet growth in this specification may not be an ideal R-plane (plane surrounded by a solid line in FIG. 16) and an ideal N-plane (plane surrounded by a solid line in FIG. 17), respectively. The R-plane and the N-plane may be an inclined face that is inclined at an angle of 50° to 65° to the C-plane, and preferably an inclined face that is inclined at an angle of 50° to 65° to the C-plane and inclined at an angle of 50° to 65° to the a-axis (any one axis of a1, a2, and a3). The nitride semiconductor function layer is a nitride semiconductor layer capable of expressing a function of a certain layer such as the light-emitting layer, the light-receiving layer, or the like. The nitride semiconductor under-layer is a nitride semiconductor layer that is positioned at the lower side (substrate side) of the nitride semiconductor function layer. In addition, the nitride semiconductor layer is a nitride semiconductor crystal layer that is represented by the formula In_{α}Al_{β}Ga_{γ}N (0≦α≦1, 0≦β≦1, 0≦γ≦1, (α+β+γ)>0). The nitride semiconductor crystal layer may be doped or undoped with an n-type dopant and/or a p-type dopant.

As illustrated in FIGS. 2 and 6, in the nitride semiconductor layer that is formed on the concave-convex surface of the substrate, the concave portions of the concave-convex face may be positioned above the convex portions of the concave-convex surface of the substrate. By forming the concave-convex face on the concave-convex surface of the substrate using the facet growth, it is possible to change the size of the oblique facet face that is formed above the concave-convex surface of the substrate, using the height and the period of the convex portions of the concave-convex surface of the substrate.

As illustrated in the schematic plan view of FIG. 14, a substrate 11 includes dot-shaped convex portions 12. In a case where a concave-convex face 13 on which at least one of the R-plane and the N-plane is exposed by the facet growth is formed on the dot-shaped convex portions 12, it is preferable that convex portions 13a of the concave-convex face 13 constitute sides of hexagons and the hexagons are arranged side by side so as to come in contact with each other, when viewed from the top of the concave-convex face 13. Since two main planes are mixed, dodecagons may be arranged side by side. In fact, as illustrated in FIG. 3, there may be a case where a hexagon is not configured since the N-plane is exposed, when it is closely observed. However, the arrangement of the convex portions of the concave-convex surface of the substrate is rotated and arranged at an angle of 30° to the main facet face, and thus the hexagons are arranged side by side in a macro. Then, the flat area of the surface decreases, and thus it is possible to improve the light-emitting efficiency and the light-receiving efficiency. In addition, as illustrated in the schematic plan view of FIG. 19, the substrate 11 includes stripe-shaped convex portions 12, and thus it is possible to form the concave-convex face 13 on which at least one of the R-plane and the N-plane is exposed by facet growth on the stripe-shaped convex portions 12.

As illustrated in FIGS. 3 and 7, it is preferable that the R-plane and the N-plane are mixed and exposed on the concave-convex face. Although the details thereof are not known, in a case where the R-plane and the N-plane are mixed and exposed on the concave-convex face, by changing the growth conditions, it is possible to control the R-plane and the N-plane, and thus a wider range of design is possible. When viewed from the top of the concave-convex face, it is preferable that the hexagon becomes a dodecagon because the surface area thereof increases. When the ratio of the R-plane and the N-plane changes during the growth depending on the growth conditions, it means that the growth rate of the growth on each face changes, and the movement of threading dislocation also changes. It is also possible to curve the dislocation in the process of changing the exposed face.

It is preferable that the inclined face included in the concave-convex face (oblique facet face) is an AlₓGa₁₋ₓN (0<x≦1) layer. For example, as a top layer or an intermediate layer, the material other than AlₓGa₁₋ₓN (0<x≦1) can be used. However, in the AlGaN (0<x≦1) layer (in which In may be included, but in which a quaternary mixed crystal is difficult to be controlled, and which is not suitable for obtaining a sufficient thickness to form the facet; in which a very small amount of In may be included, in which there is an electron doping effect such as a surfactant effect, and which may be preferable), the growth rate of the C-plane is fast, and the R-plane and the N-plane tend to be easily exposed. Therefore, the degree of freedom (for example, growth temperature, growth rate, V/III ratio, or the like) in the growth condition for obtaining the facet increases, and thus it is preferable.

Cavities may be present above the convex portions of the concave-convex surface of the substrate. For example, in FIG. 2, it can be seen that slightly elongated cavities are present at the upper right portion of the convex portions of the concave-convex surface of the substrate. This is caused by grains not being completely fitted and aggregated with each other and a slight gap between grains being remained when the facet growth continues. For example, thereby, an effect such as relaxation of distortion or warpage, effective termination to the threading dislocation, and the like (refer to FIG. 20) can be expected.

Cavities may be present on the inclined faces of the concave-convex surface of the substrate. According to FIG. 2, the cavities are caused when the grains (crystal grain boundary) that are abnormally grown on the convex portions of the concave-convex surface of the substrate are aggregated with a nitride layer having aligned faces. This is a unique effect in the facet growth, and a feature that is found in many cases of the structure in which the facet growth is continued. For example, thereby, an effect such as relaxation of distortion or warpage, effective termination to the threading dislocation, and the like can be expected.

A recess may be present in the bottom of the concave portion of the concave-convex face. This is the same as described above, and caused by the gap between grains each of which includes the facet face. This may be an essential part to realize this structure. An effect such as the prevention of the propagation of the dislocation can be considered.

### Advantageous Effects of Invention

According to the above-mentioned means, it is possible to provide the nitride semiconductor element with improved characteristics unlike in the related art.

### BRIEF DESCRIPTION OF DRAWINGS

FIG. 1 is a scanning electron microscope (SEM) image of a cross-section of a low-temperature Al_{0.1}Ga_{0.9}N fourth layer manufactured in an example 1.

FIG. 2 is a SEM image of the cross-section of the low-temperature Al_{0.1}Ga_{0.9}N fourth layer manufactured in the example 1.

FIG. 3 is a SEM image of a top view of the low-temperature Al_{0.1}Ga_{0.9}N fourth layer manufactured in the example 1.

FIG. 4 is a SEM image of a flat portion of a nitride semiconductor LED wafer according to the example 1.

FIG. 5 is a SEM image of a cross-section of an end portion of a Si-doped n-type Al_{0.1}Ga_{0.9}N third layer manufactured in the example 1.

FIG. 6 is a SEM image of the cross-section of the end portion of the Si-doped n-type Al_{0.1}Ga_{0.9}N third layer manufactured in the example 1.

FIG. 7 is a SEM image of a top view of the end portion of the Si-doped n-type Al_{0.1}Ga_{0.9}N third layer manufactured in the example 1.

FIG. 8 illustrates a PL light-emitting spectrum of a flat portion of a wafer manufactured in the example 1.

FIG. 9 illustrates a PL light-emitting spectrum of a concave-convex portion of an end portion of the wafer manufactured in the example 1.

FIG. 10 illustrates PL wavelength distribution obtained by photoluminescence (PL) measurement.

FIG. 11 illustrates PL peak intensity distribution obtained by the PL measurement.

FIG. 12 illustrates PL integral intensity distribution obtained by the PL measurement.

FIG. 13 illustrates PL full width at half maximum distribution obtained by the PL measurement.

FIG. 14 is a schematic plan view of an example of a substrate including dot-shaped convex portions that is used in the present invention.

FIG. 15 is a diagram illustrating a relationship between an inclination angle [°] with respect to a C-plane of In_{0.2}Ga_{0.8}N on GaN and total polarization discontinuity [C/m²].

FIG. 16 is a diagram graphically illustrating an R-plane.

FIG. 17 is a diagram graphically illustrating an N-plane.

FIG. 18 a schematic cross-section view of the nitride semiconductor LED wafer manufactured in the example 1.

FIG. 19 is a schematic plan view of an example of a substrate including stripe-shaped convex portions that is used in the present invention.

FIG. 20 is a scanning transmission electron microscope (STEM) image of an end portion of a nitride semiconductor LED wafer according to an example 2.

FIG. 21 is a STEM image of the end portion of the nitride semiconductor LED wafer according to the example 2.

FIG. 22 is a schematic cross-section view of a nitride semiconductor LED chip according to an example 3.

### DESCRIPTION OF EMBODIMENTS

Hereinafter, an embodiment according to an example of the present invention will be described. In the drawings used in the description of the embodiment, the same reference numerals denote the same or corresponding portions.

The present invention is an invention by which facet growth is made on a substrate (for example, Si, SiC, sapphire, GaN, or the like) having a concave-convex surface, an under-layer is formed while maintaining the shape of the facet growth or by changing the exposed face in the growth process, and a nitride semiconductor layer such as a light-emitting layer or a light-receiving layer is grown from a face that is different from the main plane of the substrate.

According to the present invention, it is possible to grow an R-plane (10-11) and an N-plane (11-21) which is rotated at an angle of 30° from the R-plane on a C-plane, and significantly improve selectivity of the growth face of the nitride semiconductor layer such as the light-emitting layer or the light-receiving layer. Further, by forming a concave-convex face using the oblique facet face, it is possible to increase the volume of the light-emitting layer or the light-receiving layer per unit plane of the substrate, and increase the light-emitting volume or light-receiving volume.

For example, in the present invention, the convex portions of the substrate are grown using a pattern with a hexagonal polka dot-shape when viewed from above. By using the shape, it is possible to form the oblique facet face having a recess portion above the convex portions of the concave-convex surface of the substrate. Thus, when the R-plane or the N-plane is completely grown, the shape of the light-emitting layer becomes a reverse hexangular pyramid shape when viewed from above. Then, in a case where the R-plane is inclined and grown at an angle of approximately 60° to the C-plane, the area of the R-plane becomes approximately 1.5 times the area of a flat plane.

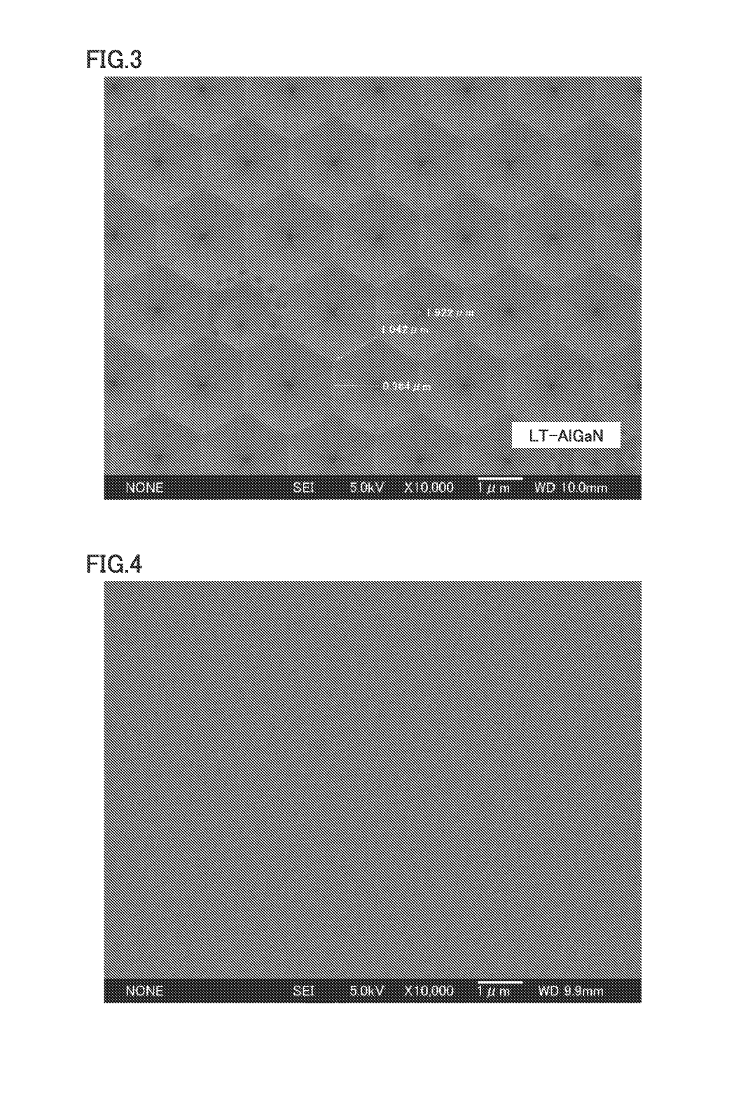

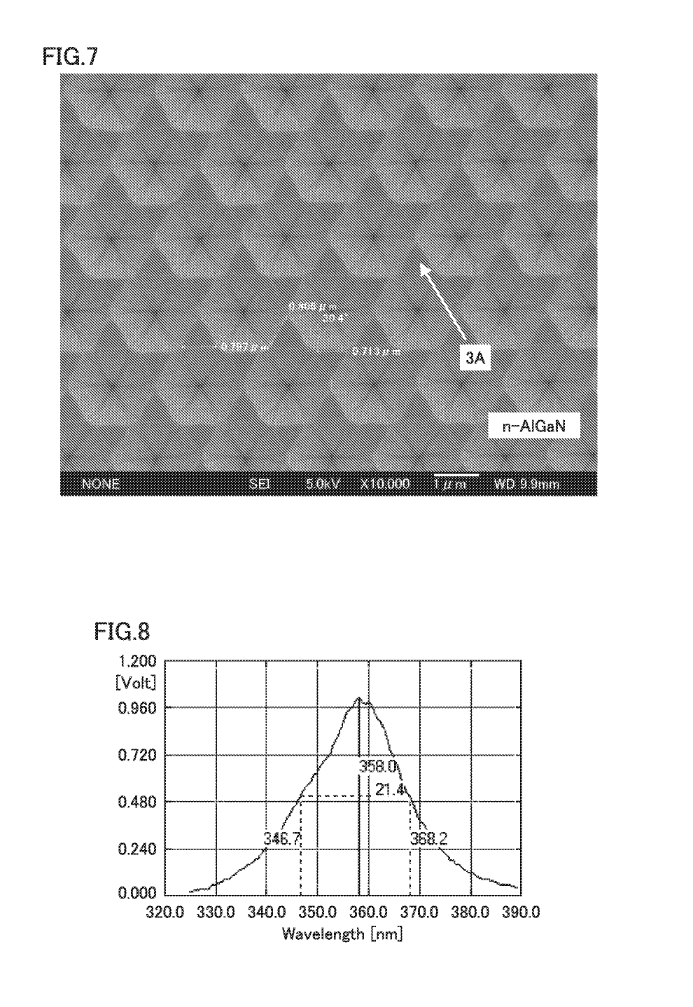

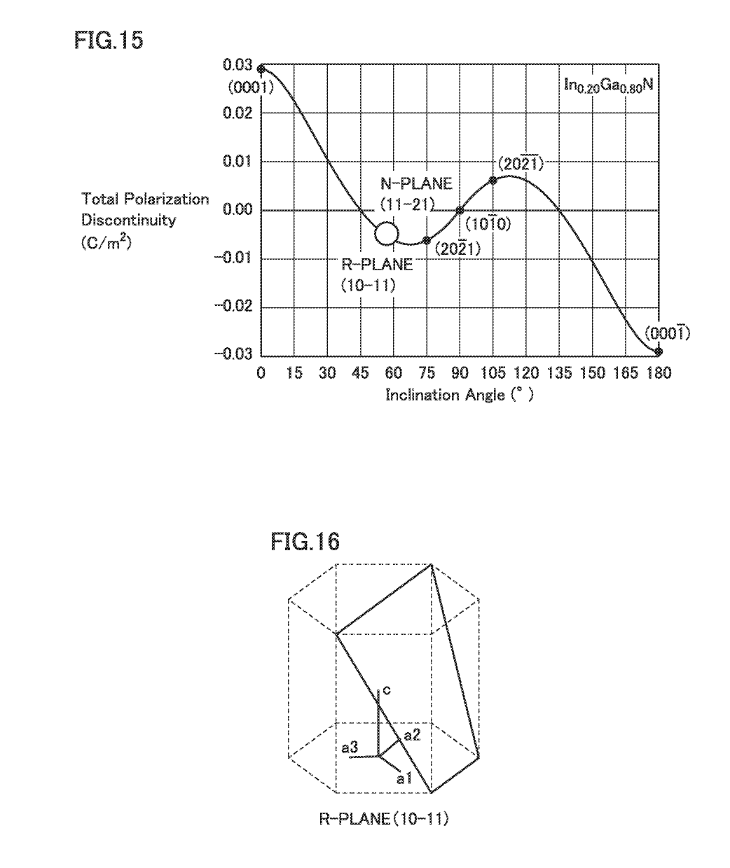

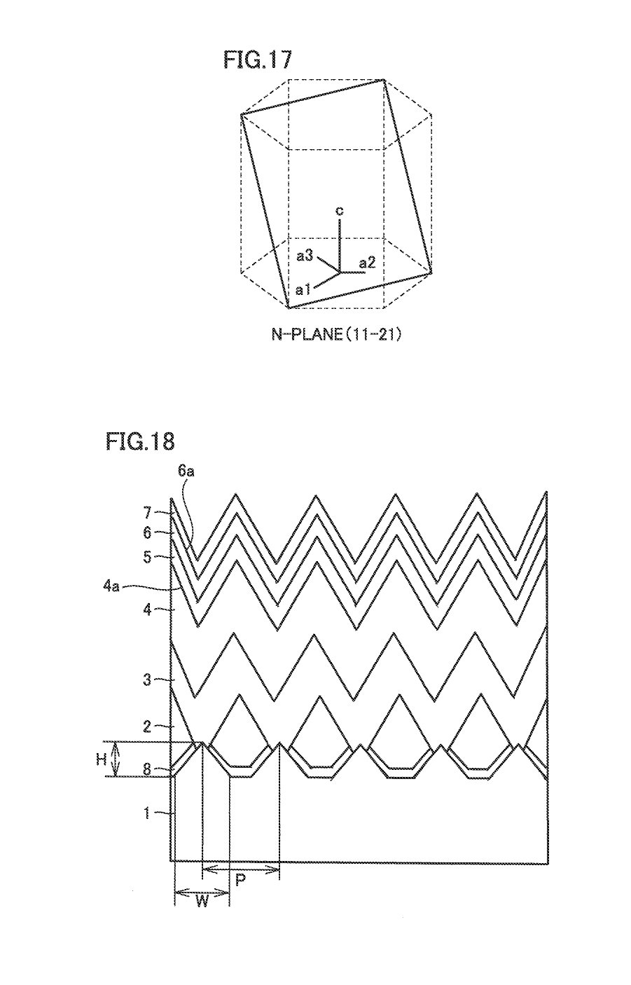

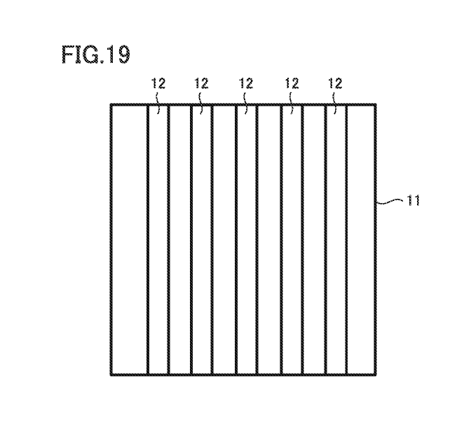

As illustrated in FIGS. 3 and 7, for example, in a case where the C-plane is selected, the R-plane and the N-plane are allowed to be grown in a form such that the R-plane and the N-plane are mixed with each other. Thus, it is possible to reduce the piezoelectric field. FIG. 15 illustrates a relationship between an inclination angle [°] with respect to a C-plane of In_{0.2}Ga_{0.8}N on GaN and total polarization discontinuity [C/m²] (refer to NPL 3). A white circle in FIG. 15 corresponds to the R-plane and the N-plane. According to this, the piezoelectric field is approximately ⅕ or less as compared with a case where the growth is made on the C-plane. This theory is applied even in a case of AlGaN/GaN interface. This leads to increase the overlap integral of a wave function and shorten the light-emitting recombination lifetime, and thus the light-emitting efficiency is improved. In addition, in nitride that has a strong c-axis orientation, it is not easy to make a good quality under-layer crystal by normal growth of the R-plane and the N-plane.

However, in the present invention, the growth is made on the C-plane by using “facet phenomenon” appeared in a specific growth condition such as low temperature, and thus the growth with the same quality as that of a case of growing a C-plane nitride layer on the C-plane (for example, an X-ray full width at half maximum, threading dislocation, a point defect, a face defect, or the like) is possible. Particularly, in non-polar growth, since the face defect (stacking fault) is propagated in a growth direction, the face defect becomes a big problem. The present invention can avoid this problem. For example, facet growth in GaN and AlGaN is possible, and thus it is possible to achieve the structure by growing “without burying”.

A case of AlGaN is presented in an example. The AlGaN has a strong three-dimensional growth factor compared to GaN, and has a wide growth allowance range of the facet growth that has a shape of the hexagon to the dodecagon in a natural formation (a case where the R-plane and the N-plane are mixed in the hexagon or the polygon with sides more than six).

It is preferable that the facets which are present at the light-emitting layer or the light-receiving layer have a shape to be fitted with each other in a spatial view, that is, that a flat face (2A of FIGS. 6 and 3A of FIG. 7) generated between the facets is in a small state. In the light extraction efficiency, an important point is how to increase the area of the oblique facet face. This is because the area of the oblique facet face decreases as the area of a flat portion increases.

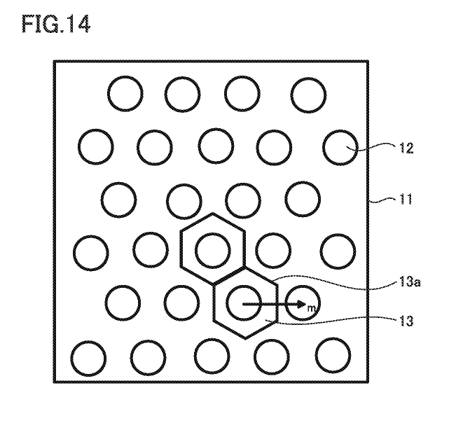

In a case where the flat face illustrated in 2A of FIGS. 6 and 3A of FIG. 7 is generated between the facets, the wavelength is changed and divided into two wavelengths. Thus, there is a possibility that the light-emitting efficiency is reduced. When the AlGaN is subjected to the facet growth in the range of 1000° C. or more, it is likely to appear as the N-plane (11-21). Therefore, as illustrated in FIG. 14, in a case where a substrate 11 includes dot-shaped convex portions 12, convex portions 13a of a concave-convex face 13 are disposed so as to configure sides of the hexagon. In a case where the sides of the hexagon configured by the convex portions 13a of the concave-convex face 13 are parallel to the side forming convex portions of a concave-convex portion of the surface of the nitride semiconductor layer such as the light-emitting layer or the light-receiving layer, the flat face representing the C-plane is reduced, and thus this is preferable. For example, in the case of the facet growth in which the R-plane is mainly exposed, it is preferable that the dot-shaped convex portions 12 of the substrate 11 are disposed to have the shortest period in the m-axis direction of the nitride semiconductor layer such as the light-emitting layer or the light-receiving layer laminated on the substrate 11.

In addition, in the case of growing an AlGaN layer at a low temperature, it is possible to switch the plane from the N-plane to the R-plane. This switching may lead to significantly change a movement of the dislocation or physical properties, for example. Further, low-temperature AlGaN can form a V-shaped pit that is capable of reducing an influence of the dislocation with respect to carriers in the light-emitting layer or the light-receiving layer. Thus, it is also considered that a concave-convex pattern is selected in anticipation of the switching event in advance, as a preferred example.

In addition, it is also possible to mix the N-plane and the R-plane without completely switching. Then, a dodecagonal facet is also possible, and the volume of the light-emitting layer or the light-receiving layer per unit area of the substrate can be increased. Thus, this is preferable. In order to upwardly propagate the facet without burying the facet layer, cavities that are formed between the facets and above the convex portions of the concave-convex surface of the substrate, play an important role. In fact, in the facet structure realized in an AlₓGa₁₋ₓN (0<x≦1) layer, the cavities are present above the convex portions of the concave-convex surface of the substrate. There is a recess portion at the bottom face of the facet (bottom of the concave portion of the concave-convex face) at which the light-emitting layer (light-receiving layer) is formed. Even though it is unclear at this moment whether or not the recess portion is a portion at which the cavity is remained above the convex portion of the concave-convex surface of the substrate without completely being buried, or whether or not the recess portion is a portion which is formed again after the cavity is buried, the recess portion can be a necessary portion.

In this growth, because face defect (stacking fault) which becomes a problem in normal semi-polar growth and non-polar growth cancels out with each other in the under-layer in the transverse direction, it is considered that the face defect does not become a problem in the semi-polar light-emitting layer which is grown on the facet face. This may be one factor to achieve high PL intensity.

For example, in the vicinity of the bottom of the facet at which the face defect is present in the quantum well structure, there is a portion that is formed so as to follow the shape of the hexagon to the dodecagon in nano order. In this structure, it is possible to reduce the warpage and the distortion of the substrate, and prevent cracks. For example, in the case of the AlGaN layer, cracks occur by the change in doping and composition. Also, cracks enter into the AlGaN layer since tensile stress is applied during bonding of the AlGaN layer and the GaN layer. However, since the a-axis direction to which the stress is applied meanders by the facet, the total distortion and stress are relaxed. Thus, cracks hardly occur.

For example, even when AlGaN or GaN is grown on the Si substrate, cracks may become a problem in some cases. The facet growth is made on the Si substrate, and the shape of the facet remains as it is. Thus, the problem is relaxed by this factor, thereby improving the degree of freedom of the growth.

The shape of the surface becomes a concave-convex shape in a natural formation, and thus it is possible to increase the light extraction efficiency. Since the damage due to etching can be reduced, it is possible to prevent oxidation or the like due to etching during contact, and contact the surface with an electrode (for example, a transparent conductive oxide film) without changing the state of the surface, compared to etching. In particular, the light extraction efficiency is a major issue in an ultraviolet region of 200 nm or more and 405 nm or less. This is because it is theoretically difficult to realize a transparent conductive oxide film having a high transmittance. As the band gap becomes larger, binding energy typically increases, and thus it is difficult to substitute atoms by a dopant or the like. Therefore, substitution of activation energy and substitution to lattice sites become difficult, and as a result, it is difficult to achieve high conductivity. However, in the present invention, the surface has a concave-convex shape as well as the concave-convex surface of the substrate, and thus it is possible to significantly increase the light extraction effect to the outside. Accordingly, as shown in the example, in PL light-emitting of a light emitting diode (LED) of 360 nm, significant light intensity improvement five times or more than that of a flat region is observed. This is an evaluation in a state where a transparent conductive film is not attached to the light-emitting layer, and thus it is considered that the difference in light intensity becomes large when light intensity is measured in a state where the transparent conductive film is attached to the light-emitting layer.

In the present invention, by changing the height and the period of the convex portions of the concave-convex surface of the substrate, it is possible to control the shape (size or the like) of the facet. For example, when it comes to the light extraction efficiency, the suitable concave-convex period is different depending on the wavelength. Therefore, there is a great advantage in the characteristics of the variable shape of the facet.

The present invention can be applied to, for example, an LED, a solar cell, a photodiode, or an electronic device.

In the LED, it can be used from a deep ultraviolet region to an infrared region (200 nm to 2000 nm). In an ultraviolet region (200 nm to 405 nm), cracks become a big problem. As described above, the direction of the distortion meanders by the concave-convex shape of the surface of the substrate, and the surface area per unit area of the substrate is increased. Thus, the warpage, the distortion and cracks are reduced.

In the ultraviolet region, the extraction efficiency becomes a big problem. This includes an example where a metal having a high reflectance is absent and an example where a transparent conductive film satisfying transparency and high conductivity is absent. In this case, the concave-convex shape of the substrate and the concave-convex shape of the surface are maintained by the concave-convex structure of the present invention, and thus the impact to the extraction efficiency is considerably large.

In addition, in the ultraviolet region, confinement of carriers also becomes a problem. This is because it is difficult to laminate a carrier block layer having a high bandgap. In this case, there is one solution in which a barrier layer having a high band offset is laminated to the light-emitting layer, but the piezoelectric field becomes large in a normal polar surface. Accordingly, an overlap between the wave function of the conduction band and the wave function of the valence band decreases, and thus the light-emitting efficiency is reduced. However, in this structure, since the piezoelectric field becomes small in semi-polarity, demerits when the band offset becomes high are reduced and the influence of the merits of the carrier confinement increases. Thus, this structure is preferable.

In a blue region (405 nm to 470 nm), it is difficult to obtain a high quality InGaN layer with a thick film. This is because equilibrium vapor pressure is significantly different between InN and GaN, and a lattice constant is also significantly different between InN and GaN, and thus this is a cause that it is difficult to obtain a high-quality mixed crystal. In addition, it is difficult to obtain a uniform film in the in-plane direction and the growth direction by migration in an In layer. Accordingly, in a case where a quantum well structure is used, GaN is typically selected as a barrier layer in many cases. In this case, in particular, in a long wavelength within the wavelength range, a lattice mismatch between the light-emitting layer (InGaN) and the barrier layer (GaN or AlGaN) becomes large, and as a result, the piezoelectric field increases. Then, in the model described above, the light-emitting efficiency decreases. Therefore, the present invention has a large merit in the wavelength range since the piezoelectric field decreases.

A large improvement in the light extraction efficiency can also be expected, since, for example, in a case where an indium tin oxide (ITO) is laminated, all of the interfaces (the concave-convex substrate/the nitride semiconductor layer, the nitride semiconductor layer/the transparent conductive film, the transparent conductive film/resin and air) have a concave-convex shape and thus the total reflection back to the inside of the layer is reduced. In addition, contact resistance also theoretically decreases since the contact area (p layer, n layer, between the electrodes) becomes larger. Since the work functions of the contact layer p-GaN and the ITO that are used in the blue region are approximately 7.0 eV and 4.3 eV, respectively, schottky contact is made at 2.7 eV.

Pinning and tunneling occur due to the defects, mutual diffusion, high carrier concentration, or the like, and thus low contact resistance (an order of 1×10⁻² Ωcm) is achieved. However, there is still room for improvement in the contact resistance. Therefore, it is considered that impact on operating voltage and power efficiency increases by increasing the contact area. In addition, there is no distortion in the face, and thus there is also a possibility that the migration in the In is changed. This is considered to greatly affect the crystallinity of the InGaN layer as the light-emitting layer. Further, a droop phenomenon or the like that causes the efficiency to be reduced at a large current density becomes a current problem. As one solution to the problem, a light-emitting layer with a thick film is given for an example. However, the decrease in the light-emitting efficiency due to the decrease in the overlap integral by the piezoelectric field becomes significant, and thus it is difficult to achieve the crystallinity while maintaining internal quantum efficiency at the current state. Aside from the crystallinity, with regard to the piezoelectric field, when this technology is used, the problem is significantly relaxed, and thus a hurdle to this technology becomes lower. Accordingly, there is a possibility that the problem will be solved by future examinations. Further, as described above, the light-emitting area increases with respect to the unit area of the substrate by the concave-convex shape, and thus it is considered that an LED which is suitable for operating at a higher current density by shifting the peak of the efficiency to a large current side is implementable.

There is a case where diffusion into the Mg light-emitting layer becomes a problem. Then, there is a possibility that the diffusion coefficient is changed by the R-plane growth or the N-plane growth. For example, there is a model that the diffusion of Mg occurs through the threading dislocation. But the threading dislocation at the face is inclined, and thus the diffusion distance becomes longer. Therefore, there is a possibility that the junction position can be close to the light-emitting layer. Then, it is possible to supply holes into the light-emitting layer at a high concentration, the holes that have high effective mass and high activation energy and that are unlikely to be supplied into the light-emitting layer at a high carrier concentration. As a result, there is a possibility that injection efficiency and carrier distribution are improved. Then, there is a possibility that the light-emitting efficiency and the droop are positively affected.

In green, red and infrared regions (480 nm to 2000 nm), as described in the description of the blue region, in a case where a GaN barrier layer is used, the band offset between the light-emitting layer and the GaN barrier layer increase. Thus, the effect according to the reduction of the piezoelectric field increases. Other merits are substantially the same as that in the blue area.

The contents of the description are also applied to a light-receiving element such as a solar cell and a photo diode. For example, the efficiency of photoelectric conversion increases by the reduction of the piezoelectric field. In addition, the light-receiving area also increases, and thus it is considered that a yield increases.

In an electronic device, it is considered that the contact resistance between the electrodes of a drain, a gate, and a source and the nitride semiconductor layer decreases from the viewpoint of the contact area.

### Example 1

As illustrated in a schematic cross-section view of FIG. 18, first, an AlN buffer layer 8 is grown on a sapphire substrate 1 that includes a concave-convex surface having a diameter of four inches and that the main plane thereof is a C-plane (pitch P of the convex portions 1a: 2 μm, width W of the convex portions 1a: 1.3 μm, height H of the convex portions 1a: 0.6 μm). Next, the temperature of the sapphire substrate 1 (growth temperature) increases to 1255° C., and an Al_{0.1}Ga_{0.9}N first layer 2 with a thickness of 36.5 μm is grown on the AlN buffer layer 8 at a growth rate of 1.5 μm/h, by using a carrier gas containing 47% nitrogen and 53% hydrogen in a molar flow rate ratio. Thereby, a facet layer with a concave-convex face having an oblique facet face (Al_{0.1}Ga_{0.9}N first layer 2) is formed.

Next, an Al_{0.1}Ga_{0.9}N second layer 3 with a thickness of 1.5 μm is grown on the Al_{0.1}Ga_{0.9}N first layer 2 by using a carrier gas containing 90% nitrogen and 10% hydrogen in a molar flow rate ratio. At this time, in the central portion of the wafer, the facet layer is buried in the Al_{0.1}Ga_{0.9}N layer 3 and disappeared, but in the end portion of the wafer, the facet layer with the concave-convex face having the oblique facet face is maintained.

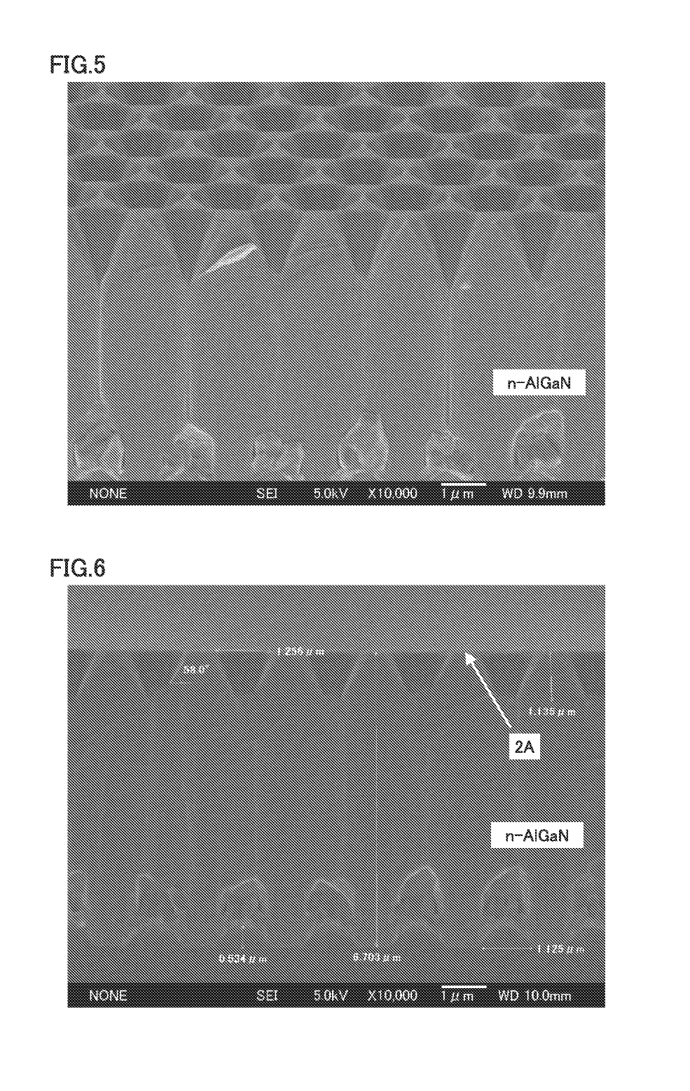

Next, a Si-doped n-type Al_{0.1}Ga_{0.9}N third layer 4 (carrier concentration: 5×10¹⁸/cm³) is grown on the Al_{0.1}Ga_{0.9}N second layer 3, under the same condition as the Al_{0.1}Ga_{0.9}N second layer 3 except for the introduction of SiH₄. At this time, the growth of the nitride semiconductor layer is stopped, and the end portion of the Si-doped n-type Al_{0.1}Ga_{0.9}N third layer 4 is observed by SEM. As a result, the facet (oblique facet face 4a) in which the N-plane is mixed with the main R-plane and exposed is observed. FIGS. 5 to 7 illustrate the results of SEM observation of the end portion of the Si-doped n-type Al_{0.1}Ga_{0.9}N third layer 4.

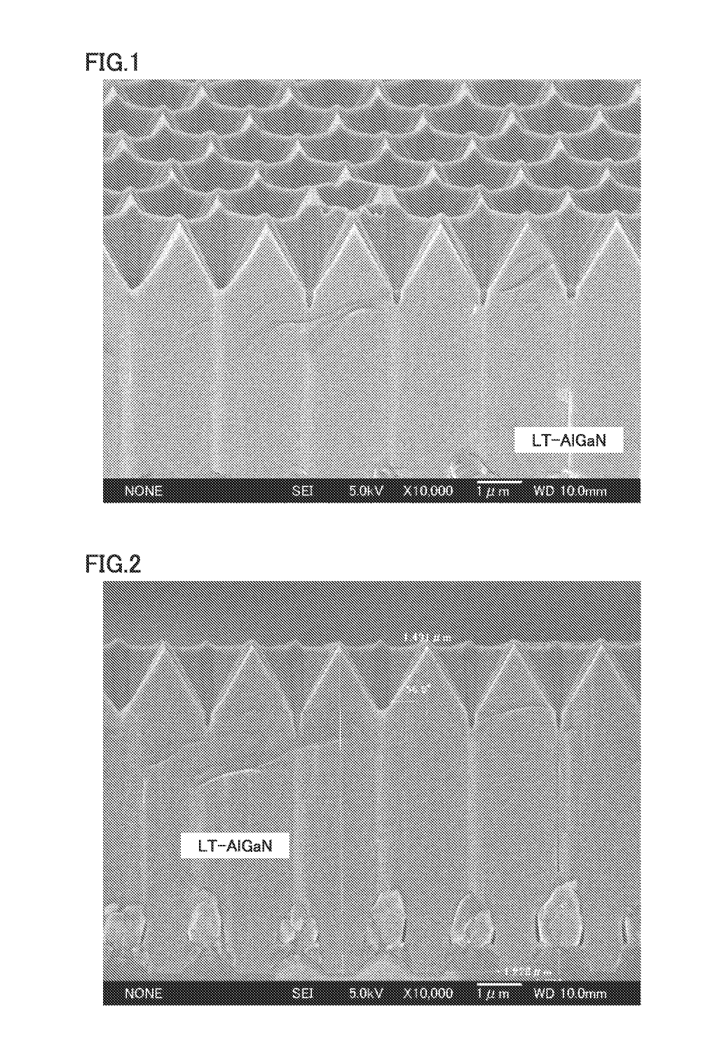

A low-temperature Al_{0.1}Ga_{0.9}N fourth layer 5 (nitride semiconductor under-layer) with a thickness of approximately 500 nm is formed on the Si-doped n-type Al_{0.1}Ga_{0.9}N third layer 4 by lowering the temperature of the sapphire substrate 1 to 930° C. and using a carrier gas containing 97% nitrogen and 3% hydrogen in a molar flow rate ratio. Here, the N-plane and the R-plane are switched, and the ratio of the R-plane increases. FIGS. 1 to 3 illustrate the results of SEM observation of the end portion of the low-temperature Al_{0.1}Ga_{0.9}N fourth layer 5.

Next, a light-emitting layer 6 (nitride semiconductor function layer) having a multiple quantum well structure is formed on the low-temperature Al_{0.1}Ga_{0.9}N fourth layer 5. Here, the light-emitting layer 6 is formed by alternately forming a barrier layer with a thickness of 20 nm that is made of Al_{0.1}Ga_{0.9}N using a carrier gas containing 97% nitrogen and 3% hydrogen in a molar flow rate ratio, and a quantum well layer with a thickness of 13 nm that is made of GaN using a carrier gas containing 90% nitrogen and 10% hydrogen in a molar flow rate ratio, one by one, for 5 cycles. The surface of the light-emitting layer 6 also has a concave-convex shape, and the N-plane and the R-plane are mixed and exposed in the oblique facet face 6a of the light-emitting layer 6.

Thereafter, after an Al_{0.1}Ga_{0.9}N barrier layer (not illustrated) with a thickness of 4 nm is formed on the light-emitting layer 6, a p-type layer 7 is formed by increasing the temperature of the sapphire substrate 1 to 1260° C., and laminating an Mg-doped p-type AlGaN, an undoped AlGaN, and an Mg-doped p-type GaN in this order. Accordingly, a nitride semiconductor LED wafer according to the example 1 is manufactured.

In the results of the examination of the outermost surface of the wafer according to the example 1, in-plane distribution due to the variation of the growth temperature is present in the wafer with a diameter of four inches, the inside of the wafer is completely filled with the film, and the outside of the wafer is formed as in the present invention. Therefore, it is considered that the growth temperature is an important factor to maintain the facet.

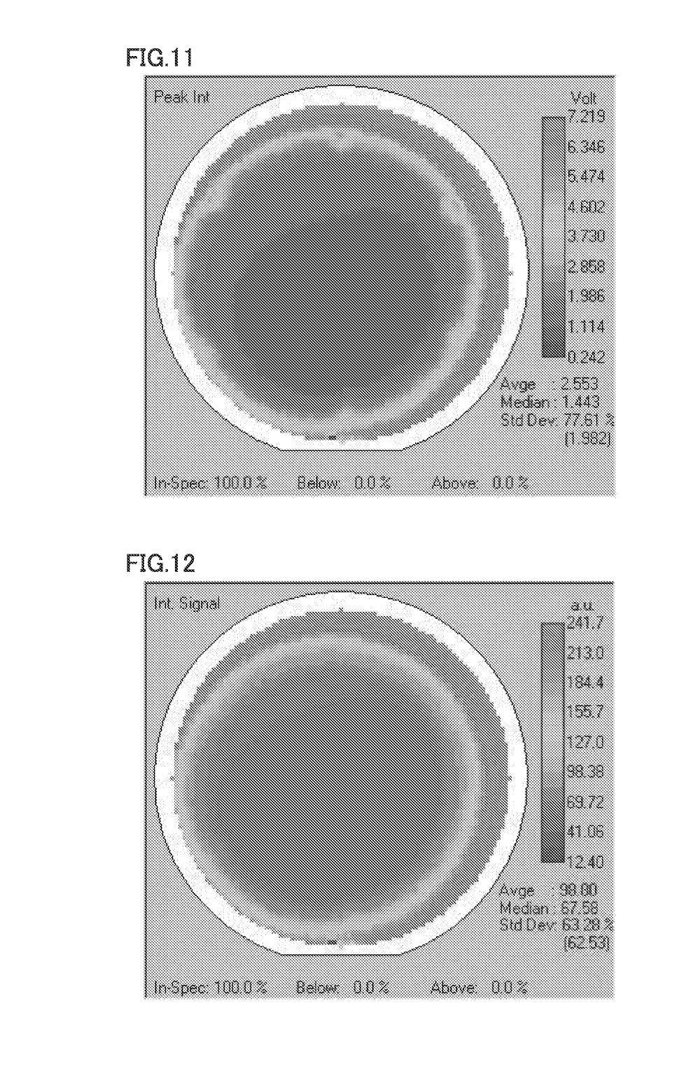

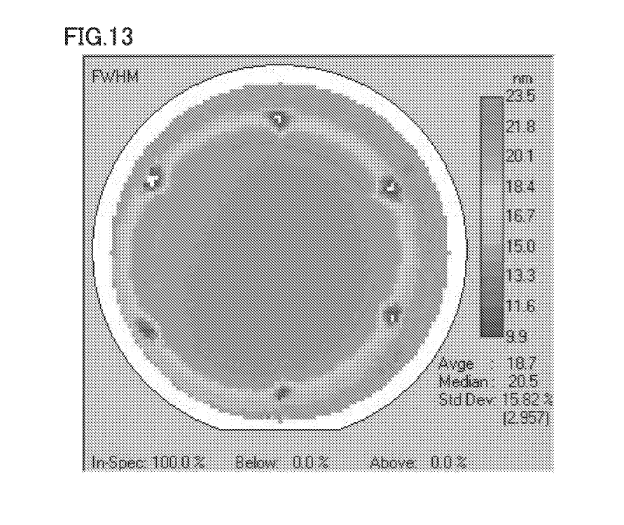

Therefore, the effect of this structure can be confirmed by comparing a portion in which the facet is buried and a portion in which the facet is remained (structure of the present invention). FIGS. 10 to 13 illustrate the results of PL measurement (excitation with YAG laser light having a wavelength of 266 nm). FIG. 10 illustrates a PL wavelength distribution, FIG. 11 illustrates a PL peak intensity distribution, FIG. 12 illustrates a PL integral intensity distribution, and FIG. 13 illustrates a PL full width at half maximum distribution.

As illustrated in FIG. 11, while the PL peak intensity is approximately 1 (a.u.) at the flat portion of the center of the nitride semiconductor LED wafer according to the example 1 illustrated in FIG. 4, the PL peak intensity is approximately 7 (a.u.) that is seven times 1 (a.u.) at the end portion in which the facet is remained (concave-convex portion). The value is a significantly high value.

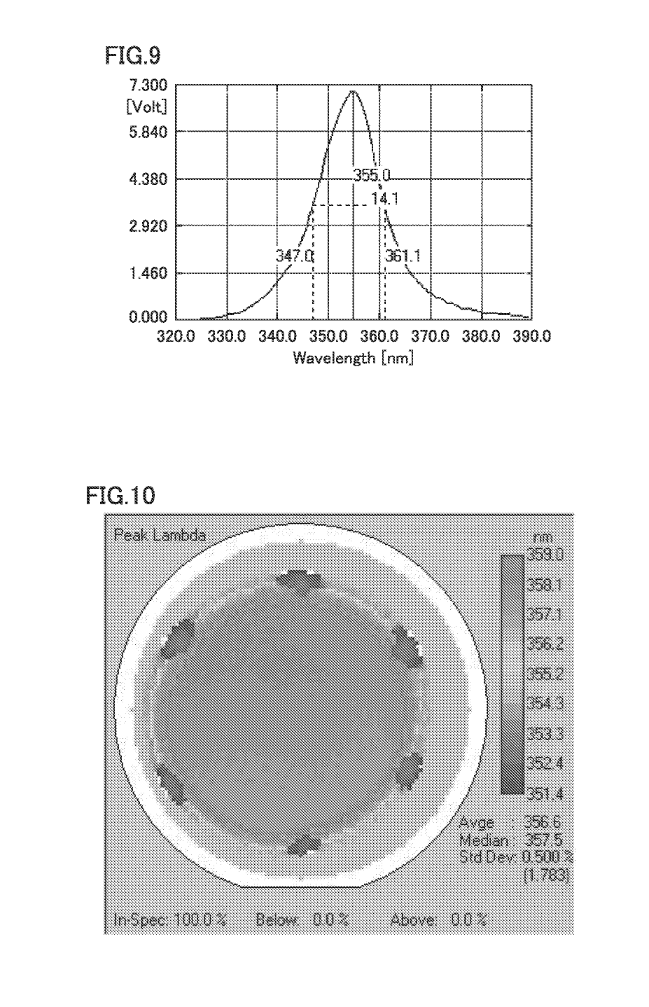

In addition, as illustrated in FIG. 10, the PL peak wavelength at the flat portion of the center is 358 nm (FIG. 8), and the PL peak wavelength at the concave-convex portion of the end portion is 355 nm (FIG. 9). The PL peak wavelength decreases at the oblique facet face of the concave-convex portion of the end portion, and thus there is a possibility that the piezoelectric field decreases at the concave-convex portion of the end portion as described above.

Further, as illustrated in FIG. 13, while the PL full width at half maximum of the flat portion of the center is 21.4 nm, the PL full width at half maximum of the concave-convex portion of the end portion is 14.1 nm. In this case, the PL full width at half maximum at the concave-convex portion of the end portion is overwhelmingly smaller than that at the flat portion of the center. Therefore, it is confirmed that crystallinity at the concave-convex portion of the end portion becomes better than that at the flat portion of the center. This is considered to be caused by a factor that a band bending is small or the like. As in the example 1, when the light-emitting layer with a thickness of 13 nm is thickly laminated in a state where the piezoelectric field is applied, the band bending is curved in an S order. Accordingly, there is a possibility that quantum levels change with respect to the growth direction and light-emitting wavelengths discretely continue. This also suggests a possibility that the piezo electric field is reduced.

In the in-plane mapping measurement of FIGS. 10 to 13, the region that has a high PL intensity is present at an outer peripheral portion, and the region that has the highest PL intensity is present at the slightly inside than an outer ring. Although a big factor determining the intensity is the facets, the difference in the intensity between the facets is still well unknown. However, a possibility that the difference is determined by the ratio in the face of the oblique facet (how small the flat portion is) or the ratio of the R-plane and the N-plane is also considered. In addition, V-shaped pits may significantly affect the difference.

The flat portion of the center is (0004) (004) 102 arcsec and (1-102) (102) 417 arcsec, and the concave-convex portion of the end portion having the oblique facet face is (0004) (004) 122 arcsec and (1-102) (102) 363 arcsec. Thus, the X-ray full width at half maximum at the flat portion of the center is comparable with that at the concave-convex portion of the end portion. Referring to the SEM image of the cross-section of the low-temperature Al_{0.1}Ga_{0.9}N fourth layer manufactured in the example 1 illustrated in FIG. 2, the R-plane (10-11) recedes. There is a possibility that the light extraction efficiency is improved by the step difference of the N-plane (11-21).

Here, a crystal orientation (0004) indicated by four variables can be expressed by (004) with three variables using a conversion, and a crystal orientation (1-102) can be expressed by (102) with three variables using a conversion.

### Example 2

A nitride semiconductor LED wafer according to an example 2 is manufactured in the same manner as in the example 1 except that, as a quantum well layer of the light-emitting layer 6, a quantum well layer that is made of InGaN in which a small amount of In (20% in a molar flow rate ratio) is added to GaN is formed (a temperature is high and a carrier gas containing 3% hydrogen in a molar flow rate ratio is used, and thus In hardly enters into GaN).

As illustrated in FIG. 14, the PL peak wavelength of the concave-convex portion of end portion of the nitride semiconductor LED wafer according to the example 2, is 362 nm. Similar to the nitride semiconductor LED wafer according to the example 1, the PL intensity of the concave-convex portion of the end portion having the oblique facet face is significantly improved than that of the flat portion of the center (the PL intensity of the flat portion of the center is 1.3 [a.u.] and the PL intensity of the concave-convex portion of the end portion is 5.4 [a.u.]).

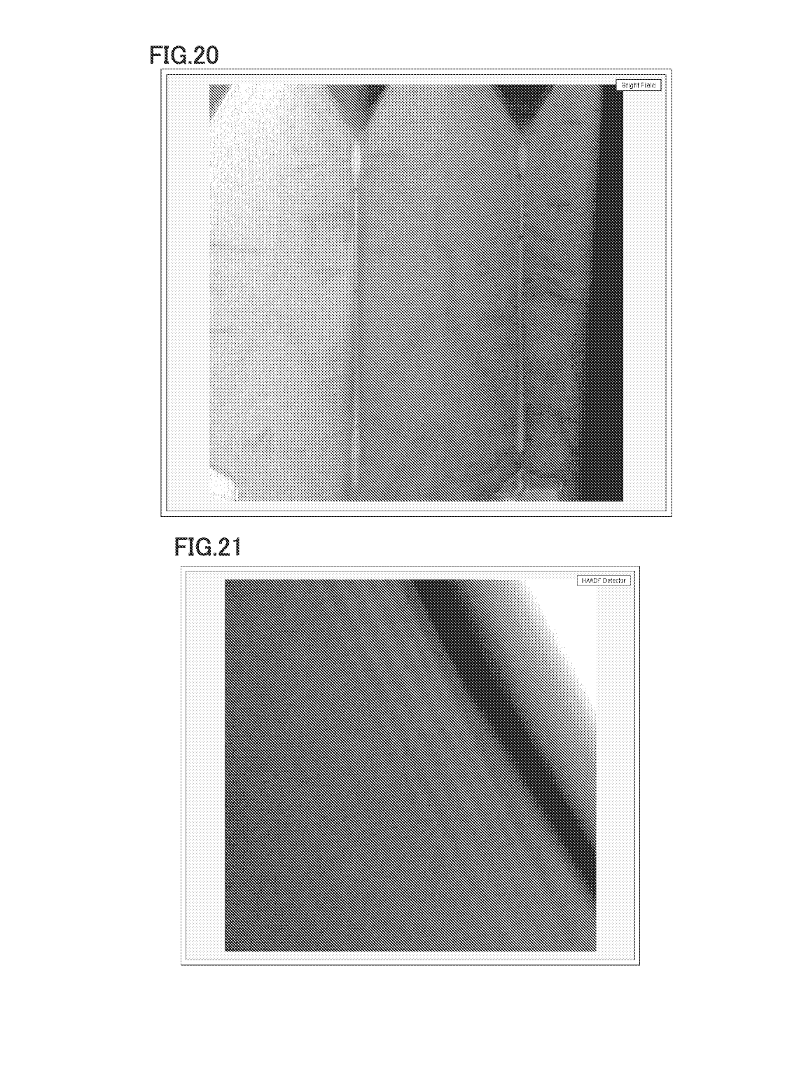

FIGS. 20 and 21 illustrate the STEM image of the end portion of the nitride semiconductor LED wafer according to the example 2. FIG. 20 illustrates that the threading dislocation curves transversely and terminates at the cavities above the convex portions of the concave-convex surface of the substrate. FIG. 21 illustrates that the periodic structure of the multiple quantum well structure of the light-emitting layer is formed to be parallel to the oblique facet face.

### Example 3

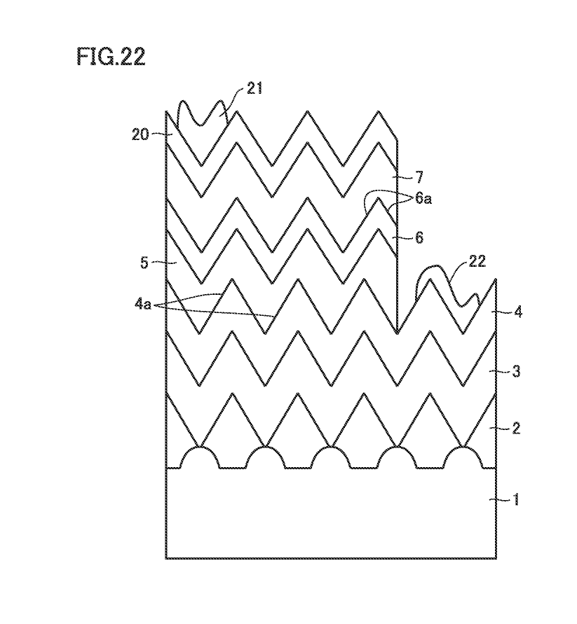

FIG. 22 illustrates a schematic cross-section view of a nitride semiconductor LED chip according to an example 3. First, the layers are formed up to the p-type layer 7 in the same manner and under the same conditions as in the example 1. Next, a transparent conductive layer 20 with a thickness of 80 nm that is made of ITO is formed on the p-type layer 7 by sputtering under the condition of a temperature of 300° C. Next, in order to expose the Si-doped n-type Al_{0.1}Ga_{0.9}N third layer 4, the transparent conductive layer 20, the p-type layer 7, the light-emitting layer 6, and the low-temperature Al_{0.1}Ga_{0.9}N fourth layer 5 are etched using a pattern by an ICP. Next, a p-side pad electrode 21 for wire connection that is made of Ti/Al is formed on the transparent conductive layer 20, and an n-side pad electrode 22 is formed on the exposed face of the Si-doped n-type Al_{0.1}Ga_{0.9}N third layer 4. Thus, the nitride semiconductor LED wafer according to the example 3 is manufactured. Next, the substrate 1 of the nitride semiconductor LED wafer according to the example 3 is divided by a laser scribing method, and thus the nitride semiconductor LED chip according to the example 3 is manufactured. When the nitride semiconductor LED chip according to the example 3 is manufactured, the form in which the faces along the R-plane and the N-plane of the low-temperature Al_{0.1}Ga_{0.9}N fourth layer remain without flattening the surface of the transparent conductive layer 20 is used.

Even in the nitride semiconductor LED wafer according to the example 3, the PL intensity is higher than that of a case where the light-emitting layer is grown on a polar surface, and thus the PL intensity in EL (electroluminescence) is also expected to be high in the same manner. Further, in the nitride semiconductor LED chip according to the example 3, it is expected that the light-emitting efficiency is unlikely to be reduced even in the high current density region (reduction of the droop phenomenon).

As described above, the embodiment and the examples according to the present invention have been described, but the configurations of the embodiment and the examples are originally intended to be combined with each other as appropriate.

The embodiment and the examples disclosed herein have been presented by way of example only, and are not intended to limit the scope of the present invention. The scope of the present invention is defined by the spirit of the claims rather than the description described above, and is intended to include equivalents of the claims and modifications within the spirit of the claims.

### INDUSTRIAL APPLICABILITY

The nitride semiconductor element according to the present invention can be applied to, for example, an electronic device, a light emitting diode, a semiconductor laser, a solar cell, a photo diode, or the like.

### REFERENCE SIGNS LIST

1 SAPPHIRE SUBSTRATE
2 Al_{0.1}Ga_{0.9}N FIRST LAYER
3 Al_{0.1}Ga_{0.9}N SECOND LAYER
3a OBLIQUE FACET FACE
4 Si-DOPED n-TYPE Al_{0.1}Ga_{0.9}N THIRD LAYER
5 LOW-TEMPERATURE Al_{0.1}Ga_{0.9}N FOURTH LAYER
6 LIGHT-EMITTING LAYER
4a, 6a OBLIQUE FACET FACE
7 p-TYPE LAYER
8 AlN BUFFER LAYER
11 SUBSTRATE
12, 13a CONVEX PORTION
13 CONCAVE-CONVEX FACE
20 TRANSPARENT CONDUCTIVE LAYER
21 p-SIDE PAD ELECTRODE
22 n-SIDE PAD ELECTRODE

1: A nitride semiconductor element comprising:
a substrate having a concave-convex surface;
a nitride semiconductor under-layer on the substrate; and
a nitride semiconductor function layer on the nitride semiconductor under-layer,
wherein the nitride semiconductor under-layer includes a concave-convex face as the surface that is composed of inclined faces that are inclined at an angle of 50° to 65° to a C-plane, and
wherein the nitride semiconductor function layer is provided on the concave-convex face of the nitride semiconductor under-layer.

2: The nitride semiconductor element according to claim 1,
wherein the inclined face is inclined at an angle of 50° to 65° to an a-axis.

3: The nitride semiconductor element according to claim 1,
wherein the concave-convex face includes at least one of an R-plane and an N-plane as the inclined face.

4: The nitride semiconductor element according to claim 1,
wherein convex portions of the concave-convex face constitute sides of hexagons and the hexagons are arranged side by side so as to come in contact with each other, when viewed from the top of the concave-convex face.

5: The nitride semiconductor element according to claim 1,
wherein the concave portions of the concave-convex face are positioned above the convex portions of the concave-convex surface of the substrate.

6: The nitride semiconductor element according to claim 5,
wherein the convex portions of the concave-convex surface of the substrate are arranged in a dot shape.

7: The nitride semiconductor element according to claim 5,
wherein cavities are present above the convex portions of the concave-convex surface of the substrate.

8: The nitride semiconductor element according to claim 1,
wherein the nitride semiconductor function layer includes a light-emitting layer, and
wherein the light-emitting layer is provided on the inclined face.

9: The nitride semiconductor element according to claim 8,
wherein the light-emitting layer is provided on at least one of the R-plane and the N-plane as the inclined face.

10: The nitride semiconductor element according to claim 8, further comprising:
a transparent conductive layer on the light-emitting layer,
wherein a portion in which at least one of the R-plane and the N-plane is not covered with the light-emitting layer and the transparent conductive layer is included.

11: The nitride semiconductor element according to claim 1,
wherein the light-emitting layer includes at least one of GaN and InGaN.
